(19) United States
(12) Patent Application Publication
(10) Pub. No.: US 2013/0170273 A1
(43) Pub. Date: Jul. 4, 2013

(54) Content-Addressable Memory Architecture for Routing Raw Hit Lines Using Minimal Base Metal Layers

(71) Applicants: Vinod Rachamadugu, Kurnool (IN); Uddip Roy, Agartala (IN); Setti Shanmuhkheswara Rao, Bangalore (IN)

(72) Inventors: Vinod Rachamadugu, Kurnool (IN); Uddip Roy, Agartala (IN); Setti Shanmuhkheswara Rao, Bangalore (IN)

(73) Assignee: LSI CORPORATION, Milpitas, CA (US)

(21) Appl. No.: 13/340,149

(22) Filed: Dec. 29, 2011

(51) Int. Cl. G11C 15/00

(52) U.S. Cl. 365/49.17

(57) ABSTRACT

A CAM circuit includes a plurality of core memory cells, each cell including comparison logic for generating a local match signal based on a comparison between stored data in the cell and a compare value. The CAM circuit includes a plurality of local match lines, each local match line coupled with a corresponding cell and adapted to convey the local match signal generated by the cell. The CAM circuit includes combination logic for receiving respective local match signals generated by a subset of the cells and for generating an output word match signal having a value indicative of the local match signals. The subset of cells is arranged with at least one block having a word size that is limited based on available space for routing tracks used to convey the local match signals and at least one word match signal in a base metal layer across the cells.

### FIELD OF THE INVENTION

The present invention relates generally to the electrical, electronic, and computer arts, and more particularly relates to content-addressable memory.

### BACKGROUND

Content-addressable memory (CAM), also known as associative memory or associative storage, is a type of memory used in, for example, certain very high speed searching applications, such as, lookup tables, databases, data compression, etc. Unlike standard computer memory (e.g., random access memory (RAM)) in which a memory address is supplied and the RAM returns the data word stored at that address, a CAM is operative to receive a search word and to search to determine if that search word is stored anywhere in the CAM. If the search word is found, the CAM returns an address of the word where the search word was found and, in some architecture, also returns a word match/miss signal. Thus, a CAM is the hardware counterpart of what in software terms would be referred to as an associative array.

CAM configured such that each of the CAM cells therein stores one of two possible logical states (e.g., “0” and “1”) is typically referred as binary CAM. Similarly, ternary CAM is configured such that each of the CAM cells stores one of the three possible logical states (e.g., “0”, “1” and “don't care”).

Because a CAM is designed to search its entire storage area (e.g., memory cells) in a single operation, it is significantly faster than RAM in virtually all search applications. As a tradeoff, however, there are some cost disadvantages to CAM. For example, unlike RAM, which utilizes comparatively simple storage cells, each individual core memory cell in a fully parallel CAM generally has its own associated comparison circuitry to detect a match between a stored data bit and an input search bit. Additionally, match line outputs from each CAM cell in a given data word are combined to yield a complete data word match/miss signal. The additional circuitry required by a CAM generally increases the physical size (i.e., layout area) and routing congestion of the CAM array, compared to RAM, which increases manufacturing cost. Consequently, CAM is typically only used in specialized applications where searching speed cannot be achieved using a less costly approach.

### SUMMARY

Principles of the invention, in illustrative embodiments thereof, advantageously provide techniques for making Raw Hit Line (RHL) outputs externally accessible in a CAM circuit of essentially any word size, without utilizing higher metal layers (e.g., metal 5 (M5) or metal 6 (M6) layers that are typically used for ASIC chip-level signal and power routing) for routing the RHLs and without modifying the power distribution network in the CAM architecture. To accomplish this, embodiments of the invention provide a unique layout architecture which frees up at least one routing track in a lower metal layer (e.g., metal 3 (M3) layer) by limiting a maximum size of a building block used to form the overall word in the CAM circuit. Not only can techniques according to embodiments of the invention be used to form a CAM of essentially any word size, such techniques can be applied to various types of CAM, including, but not limited to, binary CAM, ternary CAM and XY-ternary CAM.

In accordance with one embodiment of the invention, a CAM circuit includes a plurality of core memory cells, each memory cell including storage logic for storing data indicative of a logical state of the memory cell, and comparison logic for generating a local match signal based on a comparison between the stored data and a compare value supplied to the memory cell. The CAM circuit includes a plurality of local match lines, each local match line being coupled with a corresponding one of the memory cells and being adapted to convey the local match signal generated by the corresponding memory cell. The CAM circuit further includes combination logic operative to receive respective local match signals generated by a subset of the memory cells and to generate an output word match signal having a value indicative of respective values of the local match signals. The subset of memory cells is organized into at least one block having a word size that is limited as a function of available space for routing tracks used to convey the local match signals and at least one word match signal in a base metal layer across the memory cells to provide external access to the word match signal.

These and other features, objects and advantages of the present invention will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a schematic diagram depicting at least a portion of an exemplary CAM array in which techniques of the invention can be employed;

FIG. 2 is a block diagram depicting at least a portion of an exemplary CAM circuit which may be modified to implement techniques of the invention;

FIG. 3 is a top plan view depicting at least a portion of an exemplary layout of the illustrative CAM circuit shown in FIG. 2;

FIG. 4 is a schematic diagram depicting at least a portion of an exemplary core CAM cell suitable for use in the illustrative CAM circuit shown in FIG. 1;

FIG. 5 is a block diagram which conceptually illustrates a methodology for building an exemplary eight-bit CAM word block, according to an embodiment of the invention;

FIG. 6 is a schematic diagram depicting at least a portion of an exemplary 16-bit CAM word block formed using two 8-bit CAM word blocks, according to an embodiment of the invention;

FIG. 7 is a block diagram which conceptually illustrates a methodology for building an exemplary 32-bit CAM word block using a plurality of the 8-bit CAM word blocks shown in FIG. 5, according to an embodiment of the invention;

FIG. 8 is a block diagram which conceptually illustrates a methodology for building an exemplary 128-bit CAM word block using four 32-bit CAM word blocks, according to one embodiment of the invention;

FIG. 9 is a block diagram which conceptually depicts a methodology for building an exemplary 64-bit CAM word block using eight 8-bit CAM word blocks, according to an embodiment of the invention; and

FIG. 10 is a block diagram which conceptually depicts a methodology for building an exemplary 128-bit CAM word block using a 64-bit CAM word block and two 32-bit CAM word blocks, according to an embodiment of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Embodiments of the present invention will be described herein in the context of illustrative CAM capable of generating and routing raw hit lines (RHLs) as output pins, or alternative access means, without using higher metal layer connections (i.e., tracks), such as, for example, metal 5 (M5) or metal 6 (M6) layers, as well as methods for forming such CAM. It is to be appreciated, however, that the invention is not limited to the specific apparatus and methods illustratively shown and described herein. Rather, embodiments of the invention are directed broadly to techniques for forming a CAM which provides external access to RHLs and wherein the entire CAM array is fabricated using only lower level metal layers (e.g., metal 1 (M1) through metal 4 (M4) layers). To accomplish this, embodiments of the invention advantageously partition circuitry (e.g., compression logic) operative to generate the RHLs in a manner which preserves sufficient space in the CAM layout for routing the RHLs themselves using only a metal 3 (M3) layer.

As is known by those skilled in the art, metal layers are generally formed (e.g., deposited) on a semiconductor layer (e.g., substrate) and assigned increasingly higher numbers (e.g., M1, M2, M3, M4, etc.) which are indicative of an increasing distance above the base semiconductor layer. Thus, an M2 layer is formed on or above an M1 layer, an M3 layer is formed on or above the M2 layer, and so on. Generally, M1 and M2 layers are used for internal routing (e.g., cell interconnections). Although there is nothing preventing the use of M1 or M2 layers for routing RHLs, using M1 or M2 layers to route the RHLs would incur an increased cost primarily due to the required additional layout area. Use of M1 or M2 layers for routing RHLs, therefore, is unlikely to optimize a design tradeoff between speed and area.

Techniques of the invention beneficially reduce the overall cost of the CAM while still allowing external access to the RHLs, thereby providing added searching flexibility attributable to the RHLs. Moreover, it will become apparent to those skilled in the art given the teachings herein that numerous modifications can be made to the embodiments shown that are within the scope of the present invention. That is, no limitations with respect to the specific embodiments described herein are intended or should be inferred.

For the purposes of clarifying and describing aspects of the invention, the following table provides a summary of certain acronyms and their corresponding definitions, as the terms are used herein:

| Acronym | Definition |
|---|---|
| CAM | content-addressable memory |
| RAM | random access memory |
| RHL | raw hit line |
| WL | word line |
| BL | bit line |
| ML | match line |
| CL | compare line |
| IO | input/output |
| MISFET | metal-insulator-semiconductor field-effect transistor |
| MOSFET | metal-oxide-semiconductor field-effect transistor |
| NFET | n-channel field-effect transistor |
| PFET | p-channel field-effect transistor |
| SOC | system-on-a-chip |
| IC | integrated circuit |
| M1 | metal-1 |
| M2 | metal-2 |
| M3 | metal-3 |
| M4 | metal-4 |
| M5 | metal-5 |
| M6 | metal-6 |
| CDI | column data input |
| XOR | exclusive-OR |

The term MISFET as used herein is intended to be construed broadly and to encompass any type of metal-insulator-semiconductor field-effect transistor. The term MISFET is, for example, intended to encompass semiconductor field-effect transistors that utilize an oxide material as their gate dielectric (i.e., metal-oxide-semiconductor field-effect transistors (MOSFETs)), as well as those that do not. In addition, despite a reference to the term “metal” in the acronym MISFET, the term MISFET is also intended to encompass semiconductor field-effect transistors (FETs) wherein the gate is formed from a non-metal, such as, for instance, polysilicon.

Although implementations of the present invention described herein may be implemented using p-channel MISFETs (hereinafter called “PFETs”) and/or n-channel MISFETs (hereinafter called “NFETs”), as may be formed using a complementary metal-oxide-semiconductor (CMOS) fabrication process, it is to be appreciated that the invention is not limited to such transistor devices and/or such a fabrication process, and that other suitable devices, such as, for example, bipolar junction transistors (BJTs), etc., and/or fabrication processes (e.g., bipolar, BiCMOS, etc.), may be similarly employed, as will be understood by those skilled in the art. Moreover, although embodiments of the invention are typically fabricated in a silicon wafer, embodiments of the invention can alternatively be fabricated in wafers comprising other materials, including but not limited to gallium arsenide (GaAs), indium phosphide (InP), etc.

In general, a CAM device includes an array of memory cells (core CAM cells) arranged into rows and columns, where each row comprises a number of memory cells configured for storing one “word” and corresponding word compare logic. The number of memory cells in a given word (i.e., word size) may range between 2 and about 512, although the invention is not limited to any specific number of cells in a word. The number of memory cells may be coupled to a plurality of local match lines (i.e., “bit match lines” or “compare lines”) which, when combined through a hierarchy of logic stages, form a match line signal for the entire word. The match lines can be configured in a single-ended or differential (i.e., complementary) architecture. The hierarchical generation of a word match line signal enables a number of bit match lines to be combined without using an excessive number of metal tracks (i.e., connections) to route the bit match lines together.

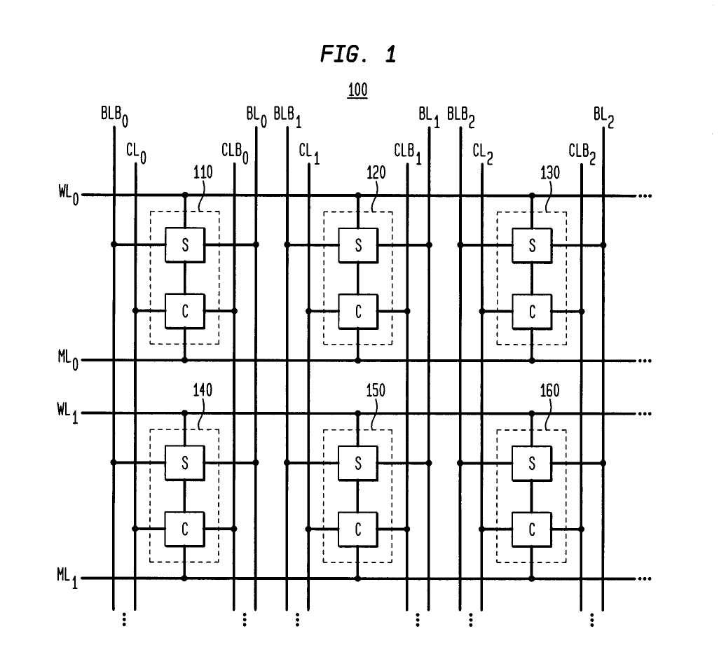

FIG. 1 is a schematic diagram depicting at least a portion of an exemplary CAM array 100 in which techniques of the invention can be implemented. CAM array 100 includes a plurality of memory cells 110, 120, 130, 140, 150 and 160. The CAM cells in CAM array 100 are organized into two rows and three columns; however, it is to be appreciated that the CAM cells may be organized into substantially any other number of rows and columns, or any other conceived arrangement, as desired. In the embodiment shown, CAM cells 110-130 represent the three columns of row 0, and CAM cells 140-160 represent the three columns of row 1.

Each CAM cell includes storage logic (S) and comparison logic (C). The storage logic in a given CAM cell stores charge that identifies a logical state (e.g., “0” or “1”) of the cell, and the comparison logic generates a local match line (ML) signal based on the data value stored within the storage logic and a compare value supplied to compare lines (CLs) coupled to the given CAM cell. Each row of cells is coupled to a corresponding word line (WL) for receiving a word line signal that activates the storage logic in each cell for reading and writing data. The CAM cells 110-130 of row 0, for example, are coupled to word line WL₀, while CAM cells 140-160 of row 1 are coupled to word line WL₁.

The storage logic in each CAM cell is coupled to corresponding bit lines (BLs) for receiving bit line signals, complementary bit line signals (BL and BLB) in this embodiment, which are shared with other cells in the same column. For example, CAM cells 110 and 140 of column 0 are coupled to complementary bit lines BL₀ and BLB₀, CAM cells 120 and 150 of column 1 are coupled to complementary bit lines BL₁ and BLB₁, and CAM cells 130 and 160 of column 2 are coupled to complementary bit lines BL₂ and BLB₂. To read data from a particular cell, the word line coupled to that cell is asserted, causing the cell to transfer charge from the storage logic onto the bit lines. To write a data value into a particular CAM cell, the data value is placed onto the bit lines coupled to that cell. Activating the cell's corresponding word line then causes the cell to transfer the data value from the bit lines into the storage logic.

The comparison logic in each cell is coupled to the storage logic and to a pair of complementary compare lines (CL and CLB), which are shared with other cells in the same column. For example, CAM cells 110 and 140 of column 0 are coupled to compare lines CL₀ and CLB₀, CAM cells 120 and 150 of column 1 are coupled to compare lines CL₁ and CLB₁, and CAM cells 130 and 160 of column 2 are coupled to compare lines CL₂ and CLB₂. In each CAM cell, the comparison logic generates a match line signal based on the data value stored within the storage logic and the compare value supplied to the compare lines. For example, a “match” (i.e., “hit”) signal may be generated if the compare value matches the stored data value; otherwise, a “miss” (i.e., “no match”) signal may be generated.

Memory cells are typically accessed in words. As previously stated, memory words comprise at least two contiguous memory cells on the same row and share a common word line, and in some cases, a common match line. The CAM array 100 shown in FIG. 1, for example, is constructed using three-bit words, including a first word comprising CAM cells 110-130, and a second word comprising CAM cells 140-160. The individual (local) bit match line signals generated within each memory cell are supplied to a common match line (e.g., ML₀ for row 0, or ML₁ for row 1) to generate a match line signal for the entire word (referred to herein as a “word match line signal”). A “hit” may be generated for the entire word when the compare bit pattern exactly matches the sequence of bits in the corresponding data word. However, if at least one compare bit fails to match a respective data bit, a “miss” will be generated for the entire word.

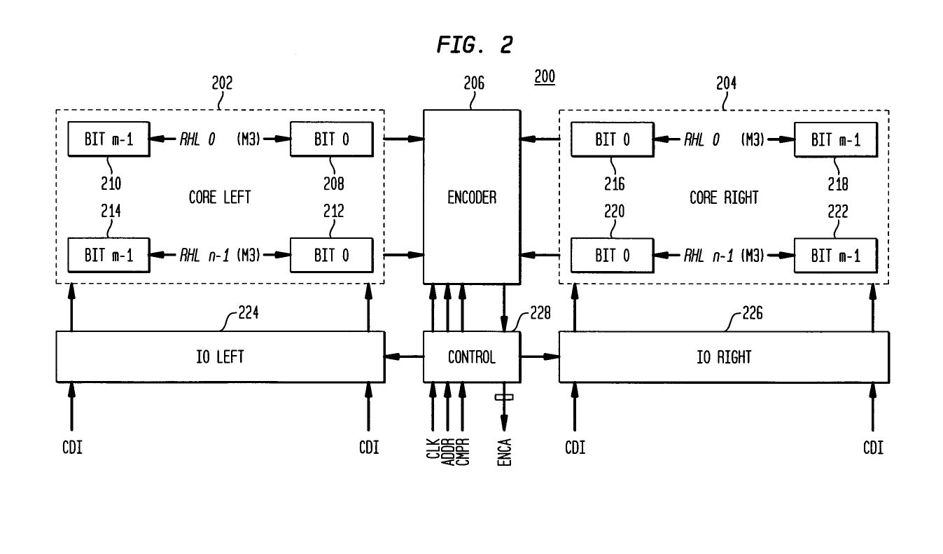

FIG. 2 is a block diagram depicting at least a portion of an exemplary CAM circuit 200 which can be modified to implement techniques of the invention. CAM circuit 200 includes a CAM array organized in a center-decode architecture. Specifically, CAM circuit 200 includes a left core 202 and a right core 204 coupled with an encoder 206 situated in the center of the CAM circuit (i.e., between the left and right cores). Each of the left and right cores 202, 204 includes a plurality of CAM cells and associated bit lines, word lines, match lines and compare lines (not explicitly shown here for clarity). The left core 202 includes CAM cells 208 (Bit 0 of row 0), 210 (Bit m−1 of row 0), 212 (Bit 0 of row n−1) and 214 (Bit m−1 of row n−1), where m and n are integers which can be the same or different relative to one another. Similarly, the right core 204 includes CAM cells 216 (Bit 0 of row 0), 218 (Bit m−1 of row 0), 220 (Bit 0 of row n−1) and 222 (Bit m−1 of row n−1). Thus, in this embodiment, the CAM is organized into an array of n rows and m columns; however, it is to be understood that the invention is substantially not limited to any specific organization of the CAM cells. The left core 202 and right core 204, collectively, represent the plurality of CAM cells in the CAM circuit 200.

CAM circuit 200 further includes input/output (IO) circuitry, organized as a left IO block 224 and a right 10 block 226, and control circuitry 228 situated between the left and right IO blocks. The left and right 10 blocks 224 and 226, respectively, function as an interface between signals and/or circuitry external to the CAM circuit 200 and the internal core circuitry (e.g., left and right cores 202, 204). The left IO block 224 and right 10 block 226, collectively, represent a plurality of IO circuits in the CAM circuit 200. Each of the left and right IO blocks 224 and 226, respectively, is operative to receive column data input (CDI) signals associated with each of the bit lines in the CAM circuit 200 and to supply this information to the corresponding columns in the left and right cores 202 and 204, respectively. The CDI information is used in the compare operation to determine whether a match exists with the data stored in the corresponding CAM cells. The control circuitry 228 is operative to receive at least a clock input signal (CLK), an input address bus (ADDR) and a compare enable signal (CMPR), and to generate an encoded address signal (ENCA) as an output of the CAM circuit 200. The input address bus is used to access one or more CAM cells and the compare enable signal is used to enable the compare operation.

The encoder 206 is preferably adapted to receive a plurality of RHLs from the left and right cores 202 and 204, respectively, and to generate a matched address signal, which forms at least part of the encoded address signal ENCA, as a function of the RHLs. Encoders suitable for use with the CAM circuit 200 will be known by those skilled in the art; implementation of the encoder 206 is not critical to the invention. Each m-bit word generates its own corresponding RHL. More specifically, all CAM cells in a particular word are compared and the hit/miss information for the cells is combined, preferably using NAND and/or NOR logic (described in further detail below), to generate a final output referred to herein as the RHL for that word. The RHLs for each of the left and right cores 202 and 204, respectively, are designated RHL 0 through RHL n−1, corresponding to the n word lines 0 through n−1, respectively, in the CAM circuit 200.

Conventionally, the RHLs are routed internally, using M3 tracks (i.e., connections), directly to the encoder 206, as shown in FIG. 1. The encoder is operative to receive the respective RHLs as inputs thereto and to generate an address location of the word where a match is found as a function of the RHL inputs. However, the RHLs in a standard CAM circuit are not, themselves, generally accessible as external outputs. Making the RHLs available as external outputs of the CAM circuit requires modification of the existing CAM architecture. Without modification of the CAM architecture, bringing the RHL outputs to the top would require using tracks formed in a higher level metal layer (e.g., M5 or M6), which poses significant challenges at an application-specific integrated circuit (ASIC) level. Consequently, standard CAM circuits are limited to a very restricted usage of the compare information otherwise available from the RHLs.

As depicted in FIG. 2, one way to make the RHL compare information externally available is to bring the RHL outputs to the top using, for example, M3 or M5 tracks. Unfortunately, however, in a typical high-density CAM circuit, M3 usage is almost entirely restricted because of the routing of the NAND-NOR logic over the CAM array, as previously stated. Moreover, aside from the disadvantages of using a higher metal layer such as M5 or M6, metal layer M5 is also commonly used for the power distribution network to the CAM memory array from the chip level.

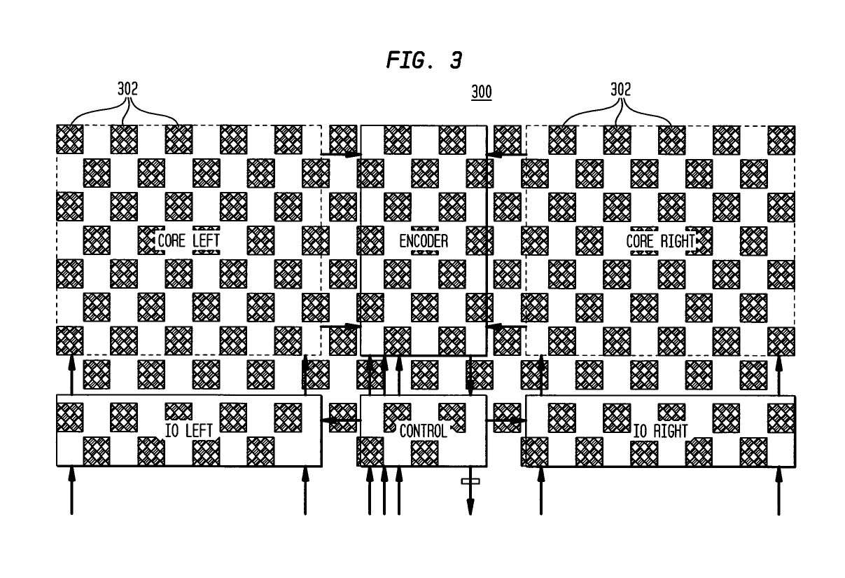

By way of example only, FIG. 3 is a top plan view depicting at least a portion of an illustrative chip layout 300 of the CAM circuit 200 shown in FIG. 2. Only the M5 layer is shown in layout 300 for clarity. More particularly, layout 300 includes a plurality of conductive vias 302 formed in the M5 layer for the purpose of power distribution from the chip (e.g., system-on-a-chip (SOC)) to the external power connections on the chip. This M5 layer distribution is typically routed (e.g., using an automated place and route algorithm, or alternative routing means) based at least in part on optimized current density requirements for the chip. As apparent from FIG. 3, the M5 distribution is so dense that it would be virtually possible to route free M5 tracks for RHLs for each word in the CAM circuit without significantly altering the power distribution network.

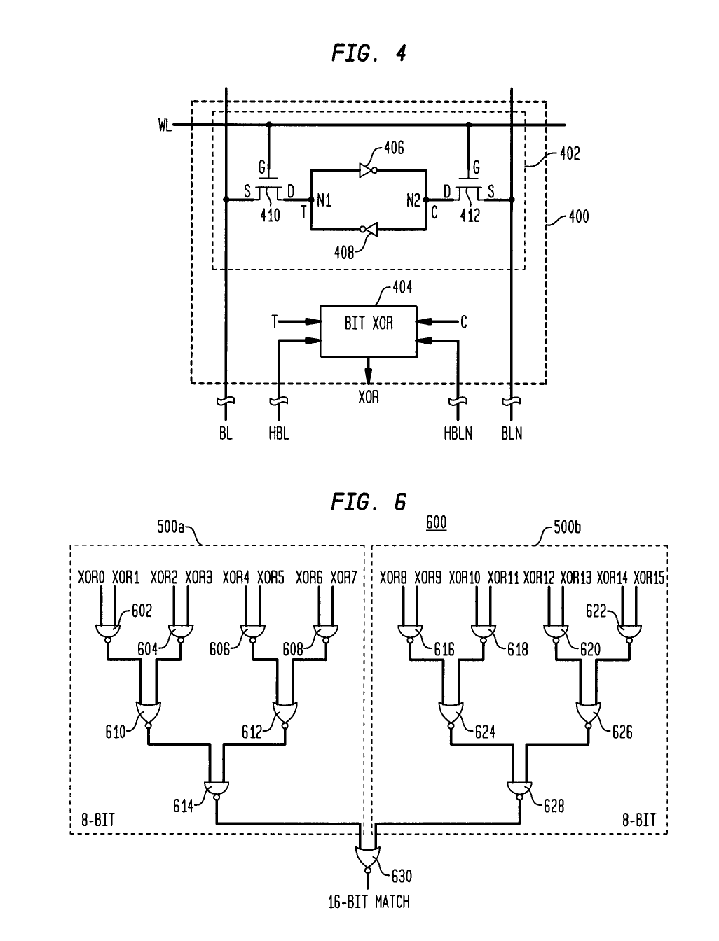

FIG. 4 is a schematic diagram depicting at least a portion of an exemplary core CAM cell 400 suitable for use in the illustrative CAM circuit 100 shown in FIG. 1. As previously stated, CAM cell 400 comprises storage logic 402 and comparison logic 404. The storage logic 402 is operative to store charge indicative of a logical state (e.g., “0” or “1”) of the cell, and the comparison logic 404 generates a local match line signal (XOR) based on the data value stored within the storage logic and a compare value supplied to complementary compare lines (i.e., hit bit lines), HBL and HBLN, corresponding to the CAM cell 400.

The storage logic 402 in the CAM cell 400 is coupled to a corresponding word line, WL, for receiving a word line signal, which is shared with other CAM cells in the same row. The word line signal is used to activate the storage logic in a corresponding cell for reading and writing data from/to the cell. The storage logic 402 is also coupled with corresponding complementary bit lines, BL and BLN, which may be shared with other CAM cells in the same column, for accessing (e.g., reading and writing) the cells. The storage logic 402 includes a pair of inverters, 406 and 408, connected in a cross-coupled configuration to form a latch. An input of inverter 406 and an output of inverter 408 are connected to bit line BL via a first access NFET 410, and an output of inverter 406 and an input of inverter 408 are connected to bit line BLN via a second access NFET 412. More particularly, a source (S) of NFET 410 is adapted for connection to bit line BL, a drain (D) of NFET 410 is connected to the input of inverter 406 and the output of inverter 408 at node N1, a gate (G) of NFET 410 is adapted for connection to word line WL, a source of NFET 412 is adapted for connection to bit line BLN, a drain of NFET 412 is connected to the output of inverter 406 and the input of inverter 408 at node N2, and a gate of NFET 412 is adapted for connection to the word line WL. A true data signal (T) is generated at node N1 and a complement data signal (C) is generated at node N2.

The comparison logic 404, which is preferably a static bitwise exclusive-OR (Bit XOR) circuit, is operative to receive the true and complement data signals, T and C, respectively, indicative of the stored data value, and a compare value supplied to the complementary compare lines HBL and HBLN, and to generate a local match signal (XOR) indicative of a result of a comparison operation between the data and compare values. The local match (i.e., “hit”) signal is preferably asserted when the compare value matches the stored data value; otherwise, a “miss” (i.e., “no match”) signal is generated on the local match line.

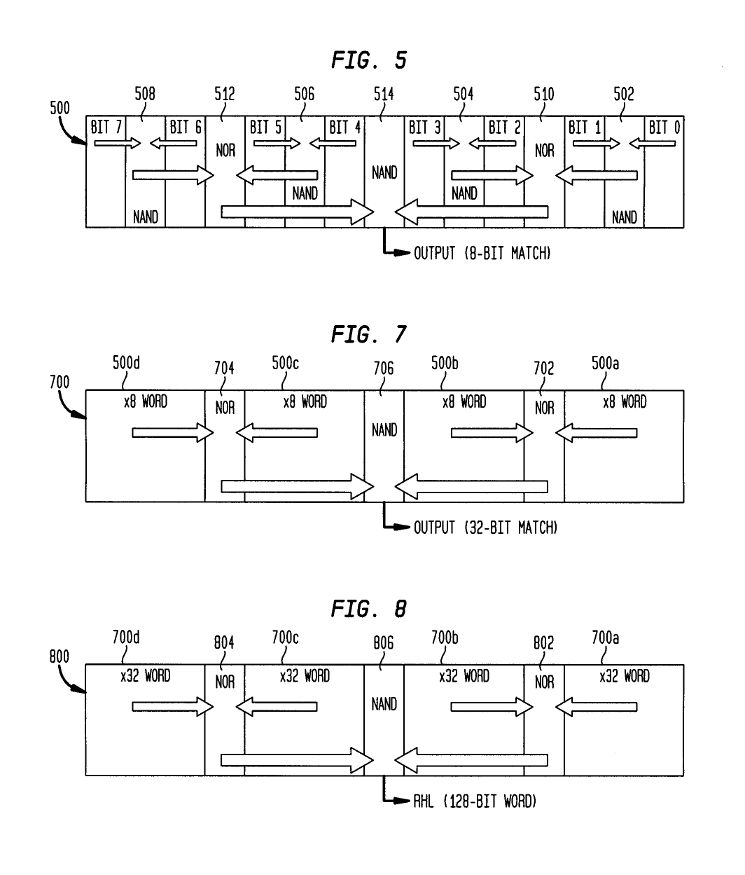

With reference now to FIGS. 5 through 8, a methodology for building an illustrative 128-bit CAM word block from a plurality of smaller CAM word blocks is conceptually shown. By way of example only, FIG. 5 is a block diagram which conceptually illustrates a method for combining comparison logic with a plurality of individual CAM cells to build an exemplary eight-bit CAM word block 500, according to an embodiment of the invention. Word block 500 comprises eight core CAM cells, Bit 0 through Bit 7, and associated combination logic. As shown in this embodiment, the combination logic is comprised of alternating stages of NAND and NOR logic gates operatively coupled between every two adjacent bits, then four bits, then eight bits. Although this ANDing functionality can be implemented using a wide variety of logic circuit configurations, as will become apparent to those skilled in the art given the teachings herein, the alternating NAND/NOR arrangement depicted in FIG. 5 represents a simple and intuitive design approach. The plurality of logic gates in the combination logic comprises a hierarchy of alternating stages of NAND and NOR gates that are collectively operative to sum the respective local match signals generated by a corresponding subset of the plurality of memory cells and to generate, for each CAM word, an output word match signal.

Specifically, word block 500 includes a first logic stage comprising a first two-input NAND gate 502 adapted to receive compare output signals from adjacent CAM cells, Bits 0 and 1, a second two-input NAND gate 504 adapted to receive compare output signals from adjacent CAM cells, Bits 2 and 3, a third two-input NAND gate 506 adapted to receive compare output signals from adjacent CAM cells, Bits 4 and 5, and a fourth two-input NAND gate 508 adapted to receive compare output signals from adjacent CAM cells, Bits 6 and 7. In a second logic stage, output signals generated by NAND gates 502, 504, 506 and 508 are combined using first and second two-input NOR gates 510 and 512, respectively. More particularly, first NOR gate 510 is adapted to receive outputs from NAND gates 502 and 504 associated with adjacent Bits 0 through 3, and second NOR gate 512 is adapted to receive outputs from NAND gates 506 and 508 associated with adjacent Bits 4 through 7. In a third logic stage, output signals generated by NOR gates 510 and 512 are combined using a fifth two-input NAND gate 514 which is operative to generate an output match signal for the eight-bit word. Thus, for the match signal generated by NAND gate 514 to be asserted (e.g., logic “0”), the compare output signals from all of the CAM cells (Bits 0 through 7) must be a logic “1;” otherwise a miss is said to occur. Using this approach, along with the three logic stages, three sets of M3 tracks are required, which are represented by arrows in FIG. 5.

It is to be appreciated that, although two-input NAND and NOR gates are employed in the eight-bit CAM word block 500, the invention contemplates alternative arrangements for combining (i.e., compressing) the compare information generated by the individual core CAM cells. For example, NAND and NOR logic gates having more than two inputs may be used (e.g., three-input NAND and NOR gates). However, there are disadvantages associated with the use of multiple-input logic gates above three, not merely due to area and layout inefficiencies, but due primarily to restrictions placed on the number of stacked devices. Accordingly, two-input logic gates are preferred.

The eight-bit CAM word block 500 can be easily extended to construct higher-bit word lengths. For example, FIG. 6 is a schematic diagram depicting at least a portion of an exemplary 16-bit CAM word block 600 formed using two 8-bit CAM word blocks, according to an embodiment of the invention. Specifically, a first 8-bit CAM word block 500a, which may be formed in a manner consistent with illustrative word block 500 shown in FIG. 5, comprises a first compression logic stage including a first NAND gate 602, a second NAND gate 604, a third NAND gate 606 and a fourth NAND gate 608. Each NAND gate in the first logic stage is adapted to receive respective match line signals (XOR) from two adjacent core CAM cells (e.g., CAM cell 400 shown in FIG. 4). More particularly, NAND gate 602 is adapted to receive match line signals XOR0 and XOR1 from CAM cell Bits 0 and 1, respectively, NAND gate 604 is adapted to receive match line signals XOR2 and XOR3 from CAM cell Bits 2 and 3, respectively, NAND gate 606 is adapted to receive match line signals XOR4 and XOR5 from CAM cell Bits 4 and 5, respectively, and NAND gate 608 is adapted to receive match line signals XOR6 and XOR7 from CAM cell Bits 6 and 7, respectively.

Output signals generated by the NAND gates 602, 604, 606 and 608 in the first logic stage are fed to a second compression logic stage including first and second NOR gates 610 and 612, respectively. NOR gate 610 is adapted to receive output signals from NAND gates 602 and 604, corresponding to Bits 0 through 3, and NOR gate 612 is adapted to receive output signals from NAND gates 606 and 608, corresponding to Bits 4 through 7. Output signals from NOR gates 610 and 612 are fed to a third compression logic stage including a fifth NAND gate 614, which is operative to generate an output match signal corresponding to the first 8-bit CAM word block 500a.

Similarly, a second 8-bit CAM word block 500b comprises a first compression logic stage including a first NAND gate 616, a second NAND gate 618, a third NAND gate 620 and a fourth NAND gate 622. Each NAND gate in the first logic stage is adapted to receive respective match line signals (XOR) from two adjacent core CAM cells. More particularly, NAND gate 616 is adapted to receive match line signals XOR8 and XOR9 from CAM cell Bits 8 and 9, respectively, NAND gate 618 is adapted to receive match line signals XOR10 and XOR11 from CAM cell Bits 10 and 11, respectively, NAND gate 620 is adapted to receive match line signals XOR12 and XOR13 from CAM cell Bits 12 and 13, respectively, and NAND gate 622 is adapted to receive match line signals XOR14 and XOR15 from CAM cell Bits 14 and 15, respectively.

Output signals generated by the NAND gates 616, 618, 620 and 622 in the first logic stage are fed to a second compression logic stage including first and second NOR gates 624 and 626, respectively. NOR gate 624 is adapted to receive output signals from NAND gates 616 and 618, corresponding to Bits 8 through 11, and NOR gate 626 is adapted to receive output signals from NAND gates 620 and 622, corresponding to Bits 12 through 15. Output signals from NOR gates 624 and 626 are then fed to a third compression logic stage including a fifth NAND gate 628, which is operative to generate an output match signal corresponding to the second 8-bit CAM word block 500b.

The output match signals generated by the first and second 8-bit CAM word blocks 500a and 500b, respectively, are then combined using a final NOR gate 630 which is operative to generate the output 16-bit match signal for the overall 16-bit CAM word block 600. This match signal represents the RHL for the 16-bit word.

FIG. 7 is a block diagram which conceptually illustrates a method for building an exemplary 32-bit CAM word block 700 using four eight-bit CAM word blocks, according to another embodiment. The 32-bit CAM word block 700 includes a first eight-bit CAM word block 500a, a second eight-bit CAM word block 500b, a third eight-bit CAM word block 500c, and a fourth eight-bit CAM word block 500d operatively combined using two stages of logic circuits. Each of the eight-bit CAM word blocks 500a, 500b, 500c and 500d is preferably formed in a manner consistent with the illustrative eight-bit CAM word block 500 shown in FIG. 5, although the invention is not limited to such an architecture. More particularly, output match signals generated by adjacent eight-bit CAM word blocks 500a and 500b are fed to a first two-input NOR gate 702. Likewise, output match signals generated by adjacent eight-bit CAM word blocks 500c and 500d are fed to a second two-input NOR gate 704. The first and second NOR gates 702 and 704, respectively, form a fourth logic stage. Outputs generated by NOR gates 702 and 704 are then fed to a two-input NAND gate 706 forming a fifth logic stage. NAND gate 706 is operative to generate an output match signal for the 32-bit CAM word block 700. Using this approach, along with the five logic stages, five sets of M3 tracks are required, which are represented by arrows in FIGS. 5 and 7.

Similarly, FIG. 8 is a block diagram which conceptually illustrates a methodology for building an exemplary 128-bit CAM word block 800 using four 32-bit CAM word blocks, according to an embodiment of the invention. The 128-bit CAM word block 800 includes a first 32-bit CAM word block 700a, a second 32-bit CAM word block 700b, a third 32-bit CAM word block 700c, and a fourth 32-bit CAM word block 700d operatively combined using two stages of logic circuits. Each of the 32-bit CAM word blocks 700a, 700b, 700c and 700d is preferably formed in a manner consistent with the illustrative 32-bit CAM word block 700 shown in FIG. 7, although the invention is not limited to such an architecture. More particularly, output match signals generated by adjacent 32-bit CAM word blocks 700a and 700b are fed to a first two-input NOR gate 802. Likewise, output match signals generated by adjacent 32-bit CAM word blocks 700c and 700d are fed to a second two-input NOR gate 804. First and second NOR gates 802 and 804, respectively, form a sixth logic stage. Outputs generated by NOR gates 802 and 804 are supplied to a two-input NAND gate 806 which forms a seventh logic stage of the overall 128-bit CAM word block. NAND gate 806 is operative to generate an output match signal for the 128-bit CAM word block 800 as a function of the compare information generated by NOR gates 802 and 804. The output match signal generated by NAND gate 806 will be indicative of the final match/miss information for that 128-bit word, which is the RHL for that word. Using this approach, along with the seven logic stages, seven sets of M3 tracks are required, which are represented by arrows in FIGS. 5, 7 and 8.

In FIGS. 5 through 8, the alternating NAND and NOR logic stages are operative to perform a functional AND operation for evaluating the compare information from each of the 128 core CAM cells in the overall 128-bit CAM word block 800. While a 128-bit CAM word block is shown, this approach is expandable to theoretically build a word of any length, 2ⁿ, using n logic stages and n corresponding M3 tracks, where n is an integer. Any other word size which is not of the form 2ⁿ can also be constructed by combining the standard building blocks shown in FIGS. 5 through 8. For example, as will become apparent to those skilled in the art given the teachings herein, a 180-bit CAM word block can be formed using 128-bit, 32-bit, 16-bit and 4-bit CAM word blocks and combining these blocks using alternating NAND and NOR logic stages (in a manner consistent with the methodology depicted in FIGS. 5 through 8), where remaining free M3 tracks are used to connect these logic stages. A practical limitation of this scheme, however, is the metal track utilizations over the CAM cell array and the unavailability of free metal tracks.

For any process technology, memory cell dimensions and technology rules will primarily dictate the number of metal tracks that can be accommodated for a given memory cell. Consequently, although the word-building scheme described above may be easy to implement, there is a practical limitation on the number of bits for which this approach can be extended to build a given word location. Specifically, as previously explained, for all the cells in a CAM word, the comparator outputs are combined together (e.g., functionally ANDed) to finally generate the RHL for that word. In layout, M3 tracks are preferably used to route those comparator outputs to the respective NAND gates, and also to route the output of each NAND/NOR gate to the input of a corresponding NOR/NAND gate in a subsequent logic stage.

By way of example only and without loss of generality, for the illustrative 128-bit word shown in FIG. 8, assume that there is space available in a vertical dimension (i.e., y-dimension) for routing nine M3 tracks across a given CAM cell. This limitation of nine M3 tracks is based on the CAM cell layout and IC process technology. More particularly, when the CAM cell y-dimension is divided by the minimum M3 track width plus the minimum separation between adjacent M3 tracks, as specified by the design rules for a given IC process technology used to fabricate the CAM circuit, a maximum number of M3 tracks that can be routed through each CAM cell can be determined for that given process technology. As previously described, seven M3 tracks will be used for routing the seven logic stages to build the illustrative 128-bit word itself. In addition, the final RHL for that word must be routed to the encoder (e.g., encoder 206 in FIG. 2), leaving only one free M3 track. In order to provide external access to the RHLs, the RHL for each word must be brought to the chip boundary using two M3 tracks; the left and right CAM arrays (e.g., left core 202 and right core 204 in FIG. 2) are considered to be two separate address locations in a center-decode architecture. Consequently, since there is only one available M3 track and two M3 tracks are required, there will be an insufficient number of M3 tracks available for routing all the RHLs in the CAM circuit to the chip boundary.

In accordance with an embodiment of the invention, a modification to the illustrative word-building methodology described above in conjunction with FIGS. 5 through 8 beneficially increases the number of available M3 tracks, thereby allowing all RHLs for substantially any sized word to be routed to the chip boundary for providing external access to the RHLs. To accomplish this, an embodiment of the invention places a restriction on the maximum block size that can be used for building larger-sized words. Working backwards and taking into account the M3 track needed to route the RHL to the encoder and the two additional M3 tracks needed to route the RHLs (associated with the left and right cores) to the chip boundary, the maximum number of M3 tracks that are available for routing across a given CAM cell is six, assuming nine available M3 tracks for each CAM cell (based on cell dimensions and process technology). Since n M3 tracks are used for routing the functional AND compression logic (e.g., NAND and NOR gates) in a 2ⁿ-bit CAM word block, this novel approach places an upper limit of 64 bits (i.e., 2⁶=64) on the largest block size that can be used to build a word in the CAM circuit.

It is to be appreciated that the upper limit on the largest block size may scale up or down or may not scale at all with process technology. Rather, the upper limit on the largest block size will be a function of how many M3 tracks per cell are available. By way of example only, assume there are ten M3 tracks available in a 20-nm IC process. Eight of those M3 tracks can be used to build a basic word block of size 2⁸ or 256 for a non-RHL architecture. For a CAM architecture which provides access to the RHLs, that number will be limited to seven, since three M3 tracks are out of the available ten will be allocated to RHL routing (i.e., the M3 track needed to route the RHL to the encoder and the two additional M3 tracks needed to route the RHLs (associated with the left and right cores) to the chip boundary), thereby resulting in a maximum word block of size 2⁷ or 128. The fundamental principles according to embodiments of the invention, however, will still hold true.

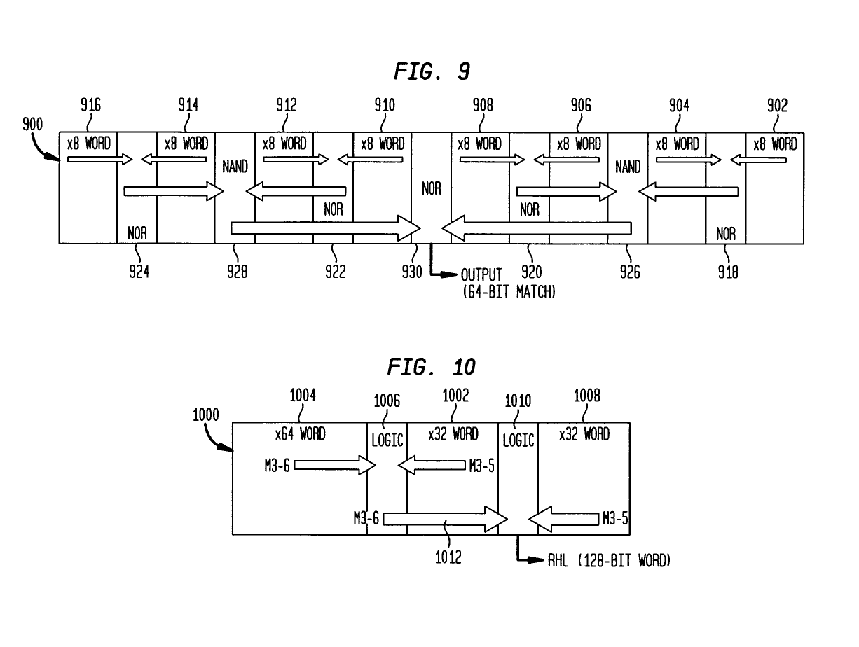

FIG. 9 is a block diagram which conceptually depicts a methodology for building an exemplary 64-bit CAM word block 900 using 8-bit CAM word blocks, according to an embodiment of the invention. Word block 900 includes a first 8-bit word block 902, a second 8-bit word block 904, a third 8-bit word block 906, a fourth 8-bit word block 908, a fifth 8-bit word block 910, a sixth 8-bit word block 912, a seventh 8-bit word block 914, an eighth 8-bit word block 916, and associated combination logic. Each of the 8-bit CAM word blocks 902 through 916 may be formed in a manner consistent with the exemplary 8-bit CAM word block 500 depicted in FIG. 5. Moreover, similar to the 8-bit word block 500 shown in FIG. 5, the combination logic in word block 900 is preferably comprised of alternating stages of NOR and NAND compression logic gates coupled between groups of two, four and eight adjacent word blocks and is operative to combine (i.e., functionally AND) the respective output match signals generated by the 8-bit word blocks.

Specifically, 64-bit CAM word block 900 comprises a first logic stage including a first two-input NOR gate 918 adapted to receive output match signals from adjacent 8-bit word blocks 902 and 904, a second two-input NOR gate 920 adapted to receive output match signals from adjacent 8-bit word blocks 906 and 908, a third two-input NOR gate 922 adapted to receive output match signals from adjacent 8-bit word blocks 910 and 912, and a fourth two-input NOR gate 924 adapted to receive output match signals from adjacent 8-bit word blocks 914 and 916. In a second logic stage, output signals generated by NOR gates 918, 920, 922 and 924 are combined using first and second two-input NAND gates 926 and 928, respectively. More particularly, first NAND gate 926 is adapted to receive outputs from NOR gates 918 and 920 associated with adjacent word blocks 902, 904, 906 and 908, and second NAND gate 928 is adapted to receive outputs from NOR gates 922 and 924 associated with adjacent word blocks 910, 912, 914 and 916. In a third logic stage, output signals generated by NAND gates 926 and 928 are then combined using a fifth two-input NOR gate 930 which is operative to generate an output match signal for the entire 64-bit word.

As apparent from FIG. 9, the 64-bit CAM word 900 comprises eight 8-bit CAM word blocks and three stages of combination logic. Each 8-bit CAM word block, which comprises eight individual core CAM cells and three stages of combination logic, requires three of the available nine M3 tracks. Therefore, the 64-bit CAM word block 900 utilizes a total of six of the nine free M3 tracks.

FIG. 10 is a block diagram conceptually depicting a methodology for building an exemplary 128-bit CAM word block 1000 using a 64-bit CAM word block and two 32-bit CAM word blocks, according to an embodiment of the invention. Specifically, with reference to FIG. 10, an output match signal generated by a first 32-bit CAM word block 1002 is combined with an output match signal generated by a 64-bit CAM word block 1004 using a first logic circuit 1006. Since, in this embodiment, the output match signals from the 64-bit word block 1004 will be of a different polarity compared to the output match signal generated by the 32-bit word block 1002 (the former generating a logic “1” output signal indicative of a match and the latter generating a logic “0” output signal indicative of a match), the combination logic circuit 1006 is preferably adapted to make the respective output match signals consistent with one another, such as, for example, by inverting one of the received output signals from either the 32-bit word block 1002 or the 64-bit word block 1004. Alternative signal translation means are similarly contemplated by the invention.

The output signal generated by logic circuit 1006 is combined with the output match signal generated by a second 32-bit word block 1008 using a second logic circuit 1010. Again, logic circuit 1010 is preferably adapted so that the respective output match signals generated by the first logic circuit 1006 and the second 32-bit word block 1008 are consistent with one another, such as, for example, by inverting one of the received output signals from either the word block 1008 or the logic circuit 1006. The output match signal generated by logic circuit 1010 will be indicative of the final match/miss information for the 128-bit word, which is the RHL for that word. This RHL will provide essentially the same result as the RHL generated by the 128-bit word block 800 shown in FIG. 8.

One concern that may arise is that, unlike the illustrative 128-bit CAM word block 800 shown in FIG. 8 which utilizes seven logic stages (i.e., 2⁷=128), the exemplary 128-bit CAM word block 1000 depicted in FIG. 10 uses eight logic stages. However, the small cost of adding one additional logic stage to the overall CAM word block comes with a substantial benefit of reducing the M3 track utilization in the CAM by one, thereby providing a sufficient number of available M3 tracks to route the RHLs to the chip boundary for allowing external access to the RHLs.

With continued reference to FIG. 10, although the 128-bit CAM word block 1000 uses eight logic stages, compared to seven logic stages used by the illustrative 128-bit CAM word block 800 shown in FIG. 8, the word block 1000 reduces the M3 track utilization by making use of a sixth parallel M3 track 1012 to route the output of logic circuit 1006 across the 32-bit word block 1002. Recall that a 32-bit CAM word block (e.g., 1002 and 1008) requires only five logic stages (2⁵=32), thereby freeing up an additional M3 track. Thus, while the inventive word-building approach which limits the maximum standard building block size to 64 bits, compared to 128 bits, may increase the number of logic stages employed, it does not restrict the number of bits for which this logic can be extended.

By way of example only and without loss of generality, consider again the formation of a 180-bit CAM word block. Using the approach described above in conjunction with FIG. 10, two 64-bit word blocks, one 32-bit block, one 16-bit block and one 4-bit block are required to build the 180-bit word block, without increasing the number of M3 tracks used to combine these blocks in the top level. This approach does add one additional logic stage, compared to conventional CAM word-building approaches, but a more significant advantage of this approach in accordance with an embodiment of the invention is that it frees up one M3 track, which beneficially solves the problem of routing the RHL signals through the array to the chip boundary, as previously explained. The gain achieved at the 128-bits block level will hold true for anything higher than 128 bits as well.

It is to be appreciated that the maximum block size can be limited to something less than 64 bits. For example, according to another embodiment of the invention, the maximum block size can be limited to 32 bits. In this scenario, an additional M3 track would be freed up at the expense of utilizing an additional logic stage. Unless the additional M3 track is critical for routing, however, the extra logic required for this approach significantly increases the total delay of the compare operation, thereby impacting the overall performance of the CAM circuit.

As the process technology continues to shrink, device delays will reduce accordingly, whereas device layout constraints and challenges will only become exacerbated. Hence, any slight increases in delay resulting from the additional logic stage used in connection with the novel word-building methodology described herein will become insignificant, while advantages of the invention will become substantial and far outweigh the cost of an added logic stage. Advantages of the novel word-building methodology include, but are not limited to, easy to route RHLs, no change in the M5 power distribution network, and the entire CAM architecture remains exactly the same while providing the encoded address as well as the RHL outputs, among other important advantages.

As an added benefit of the word-building methodology according to an embodiment of the invention, the CAM array locations can be considered as a full single word or as two separate words from the left and right cores (e.g., as in the illustrative center-decode CAM architecture 200 shown in FIG. 2). In a single-word CAM architecture, the RHLs from the left and right cores (e.g., 202 and 204, respectively, in FIG. 2) are combined together to generate a final RHL which is provided for the whole CAM word. Alternatively, in a half-word CAM architecture, two RHLs are provided. With the change in the word-building methodology according to aspects of the invention described herein and the resulting available M3 tracks, it is now possible to supply one or both RHLs as outputs of the CAM circuit. Moreover, these outputs can be routed to the chip boundary on one or both sides of the core, providing flexibility for an ASIC designer in placement and routing. Moreover, this word-building methodology can be similarly applied to essentially any type of CAM cell array, including, but not limited to, binary CAM, ternary CAM and XY-CAM. As in the case of binary CAM, where the maximum word block size is limited to 64 bits, for ternary CAM or XY-CAM, the maximum word block size is limited to 32 bits in order to free up the additional M3 tracks required to route the RHL outputs to the chip boundary across the CAM array.

At least a portion of the techniques of the present invention may be implemented in an integrated circuit. In forming integrated circuits, identical die are typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Integrated circuits so manufactured are considered part of this invention.

An integrated circuit in accordance with the present invention can be employed in essentially any application and/or electronic system in which CAM systems may be employed. Suitable systems and applications for implementing techniques of the invention may include, but are not limited to, embedded memory, pattern recognition, image processing, networking, communications, speech processing and recognition, etc. Systems incorporating such integrated circuits are considered part of this invention. Given the teachings of the invention provided herein, one of ordinary skill in the art will be able to contemplate other implementations and applications of the techniques of the invention.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. A content-addressable memory circuit formed in an integrated circuit comprising a semiconductor substrate and a plurality of metal layers formed above the substrate, each of metal layers being spaced vertically from one another, the content-addressable memory circuit comprising:
a plurality of core memory cells, each memory cell including storage logic operative to store data indicative of a logical state of the memory cell, and comparison logic operative to generate a local match signal indicative of a comparison between the stored data and a compare value supplied to the memory cell;
a plurality of local match lines, each local match line being coupled with a corresponding one of the plurality of memory cells and being adapted to convey the local match signal generated by the corresponding one of the plurality of memory cells; and
combination logic operative to receive respective local match signals generated by at least a subset of the plurality of memory cells and to generate, for each content-addressable memory word, an output word match signal having a value indicative of respective values of the local match signals generated by the subset of the plurality of memory cells;
wherein the subset of the plurality of memory cells is organized into at least one block having a prescribed maximum word size that is limited as a function of available space for routing tracks used to convey the local match signals and to convey at least one word match signal in a base metal layer across the memory cells to a boundary of the IC to thereby provide external access to the at least one word match signal.

2. The content-addressable memory circuit of claim 1, wherein the base metal layer is a metal-3 layer.

3. The content-addressable memory circuit of claim 1, wherein when a word size of the content-addressable memory circuit is greater than the maximum word size of the at least one block, the plurality of memory cells are organized into a plurality of blocks, each of the blocks having a word size which is less than or equal to the maximum word size, respective word match signals generated by the plurality of blocks being combined by the combination logic to generate the output word match signal.

4. The content-addressable memory circuit of claim 1, further comprising a plurality of bit lines, each of the bit lines coupled with a corresponding one of the memory cells, wherein the bit lines are formed in a first metal layer arranged above the semiconductor substrate, the local match lines are formed in a second metal layer spaced vertically from the first metal layer, and at least one routing track used to convey the at least one word match signal is formed in a third metal layer spaced vertically from the first and second metal layers.

5. The content-addressable memory circuit of claim 1, wherein the combination logic comprises a plurality of logic gates, each of the logic gates being arranged between a different pair of memory cells.

6. The content-addressable memory circuit of claim 5, wherein each of at least a subset of the logic gates is a functional AND gate.

7. The content-addressable memory circuit of claim 5, wherein the plurality of logic gates in the combination logic comprises a first stage and at least a second stage, the first stage including a plurality of NAND gates, each of the NAND gates having first and second inputs connected with a corresponding different pair of first and second memory cells, respectively, the second stage including at least one NOR gate having first and second inputs connected with respective outputs of a corresponding pair of NAND gates in the first stage, an output of the NOR gate generating the output word match signal.

8. The content-addressable memory circuit of claim 5, wherein the plurality of logic gates in the combination logic comprises a hierarchy of alternating stages of NAND and NOR gates operative to sum the respective local match signals generated by a corresponding subset of the plurality of memory cells and to generate, for each content-addressable memory word, the output word match signal.

9. The content-addressable memory circuit of claim 1, further comprising an encoder adapted to receive respective output word match signals generated by the combination logic, and to generate a matched address signal, the matched address signal forming at least part of an encoded address signal, as a function of the output word match signals.

10. The content-addressable memory circuit of claim 9, further comprising control circuitry coupled with the encoder, the control circuitry being operative to receive at least a clock signal and an input address bus, and to generate the encoded address signal as a function of the matched address signal.

11. The content-addressable memory circuit of claim 9, wherein the content-addressable memory circuit is formed having a center-decode architecture, such that the memory cells are arranged into one of at least two core blocks and the encoder is arranged between the at least two core blocks.

12. The content-addressable memory circuit of claim 1, wherein the maximum word size of the at least one block is 64 bits.

13. The content-addressable memory circuit of claim 1, wherein the maximum word size of the at least one block is 2ⁿ bits, where n is an integer indicative of a number of tracks used for interconnection routing in the combination logic.

14. An integrated circuit comprising at least one content-addressable memory circuit, the at least one content-addressable memory circuit comprising:
a plurality of core memory cells, each memory cell including storage logic operative to store data indicative of a logical state of the memory cell, and comparison logic operative to generate a local match signal indicative of a comparison between the stored data and a compare value supplied to the memory cell;
a plurality of local match lines, each local match line being coupled with a corresponding one of the plurality of memory cells and being adapted to convey the local match signal generated by the corresponding one of the plurality of memory cells; and
combination logic operative to receive respective local match signals generated by at least a subset of the plurality of memory cells and to generate, for each content-addressable memory word, an output word match signal having a value indicative of respective values of the local match signals generated by the subset of the plurality of memory cells;
wherein the subset of the plurality of memory cells is organized into at least one block having a prescribed maximum word size that is limited as a function of available space for routing tracks used to convey the local match signals and to convey at least one word match signal in a base metal layer across the memory cells to a boundary of the integrated circuit to thereby provide external access to the at least one word match signal.

15. The integrated circuit of claim 14, wherein the combination logic comprises a plurality of logic gates, each of the logic gates being arranged between a different pair of memory cells in the at least one content-addressable memory circuit.

16. The integrated circuit of claim 15, wherein the plurality of logic gates in the combination logic comprises a hierarchy of alternating stages of NAND and NOR gates operative to sum the respective local match signals generated by a corresponding subset of the plurality of memory cells and to generate, for each content-addressable memory word, the output word match signal.

17. The integrated circuit of claim 14, wherein the maximum word size of the at least one block is 2ⁿ bits, where n is an integer indicative of a number of tracks used for interconnection routing in the combination logic.

18. The integrated circuit of claim 14, wherein when a word size of the at least one content-addressable memory circuit is greater than the maximum word size of the at least one block, the plurality of memory cells are organized into a plurality of blocks, each of the blocks having a word size which is less than or equal to the maximum word size, respective word match signals generated by the plurality of blocks being combined by the combination logic to generate the output word match signal.

19. The integrated circuit of claim 14, wherein the base metal layer is a metal 3 (M3) layer.

20. A method for providing external access to output word match signals corresponding to respective words in a content-addressable memory circuit, the content-addressable memory circuit including a plurality of core memory cells, each memory cell including storage logic for storing data indicative of a logical state of the memory cell and comparison logic for generating a local match signal indicative of a comparison between the stored data and a compare value supplied to the memory cell, a plurality of local match lines, each local match line being coupled with a corresponding one of the plurality of memory cells and being adapted to convey the local match signal generated by the corresponding one of the plurality of memory cells, and combination logic operative to receive respective local match signals generated by at least a subset of the plurality of memory cells and to generate, for each content-addressable memory word, an output word match signal having a value indicative of respective values of the local match signals generated by the subset of the plurality of memory cells, the method comprising the steps of:
determining, for a given integrated circuit process used to fabricate the content-addressable memory circuit, an amount of space available for routing tracks used to convey the local match signals and to convey the output word match signal in a base metal layer across the memory cells to a boundary of an integrated circuit in which the content-addressable memory circuit is formed;
determining a maximum word block size for the content-addressable memory circuit as a function of the determined amount of space available for routing tracks;
combining a plurality of blocks of memory cells using the combination logic, each of the plurality of blocks having a word size associated therewith that is less than or equal to the maximum word block size, to thereby generate the output word match signal for a corresponding word in the content-addressable memory circuit;
routing output word match signals corresponding to respective words in the content-addressable memory circuit using base metal layer tracks across the memory cells to a boundary of an integrated circuit in which the content-addressable memory circuit is formed to thereby provide external access to the output word match signals.
